(19) United States
(12) Patent Application Publication
(10) Pub. No.: US 2009/0296448 A1
(43) Pub. Date: Dec. 3, 2009

(54) DIODE AS VOLTAGE DOWN CONVERTER FOR OTP HIGH PROGRAMMING VOLTAGE APPLICATIONS

(76) Inventors: Fu Lung Hsueh, Cranbury, NJ (US); Shine Chung, San Jose, CA (US); Wen-Kuan Fang, Taipei (TW)

Correspondence Address: K & L GATES LLP;IP Docketing, 630 Hansen Way, Palo Alto, CA, 94304, US

(21) Appl. No.: 12/367,455

(22) Filed: Feb. 6, 2009

Related U.S. Application Data
(60) Provisional application No. 61/057,503, filed on May 30, 2008.

(51) Int. Cl. G11C 17/06; G11C 5/14; G11C 17/00; G11C 7/00

(52) U.S. Cl. 365/105; 365/226; 365/94; 365/189.11

(57) ABSTRACT

A voltage down converter for programming a one-time-programmable (OTP) memory comprising is disclosed, the voltage down converter comprises a bonding pad for coupling to a programming power supply, and at least one forward biased diode coupled between the bonding pad and the OTP memory, wherein a programming voltage received by the OTP memory is lowered from the programming power supply by the voltage drop across the forward biased diode.

### CROSS REFERENCE

This application claims the benefits of U.S. Provisional Patent Application Ser. No. 61/057,503, which was filed on May 30, 2008, and entitled “DIODE AS VOLTAGE DOWN CONVERTER FOR OTP HIGH PROGRAMMING VOLTAGE APPLICATIONS.”

### BACKGROUND

The present invention relates generally to integrated circuit (IC) design, and more particularly to voltage down converter for externally programming memories.

In a deep submicron technology for a typical IC chip, device feature sizes, such as gate oxide thickness and channel length, have greatly reduced. In order to work with such small geography devices, the power supply voltage have to be lowered, otherwise the gate oxide may breakdown and the transistor channel may punch through. For instance, for a 90 nm technology, the power supply voltage is about 1.0V. However, in a system level, i.e., outside the IC chip, a power supply voltage may still be 2.5V or 3.3V. In order to allow such deep submicron IC chip to properly work in the high voltage system, voltage down converters have to be employed to convert an external high voltage power supply to a predetermined internal low voltage power supply.

In case of one-time-programmable (OTP) memory, a programming voltage from an external source also needs to be converted to a lower internal programming voltage. Conventionally, a voltage reference is used in this voltage down converting. However, due to high peak driving current requirement, the conventional voltage down converter may take up a large layout area. Besides, the conventional voltage down converter is more complicated to design. As different customers may have different voltage requirements, OTP memories that use the conventional voltage down converter will require longer design cycles. Even though the conventional voltage down converter using the reference voltage approach provides good accuracy, it is often an over kill for the OTP memory programming application.

As such, what is desired is a simple and effective voltage down converter fits the OTP memory programming application.

### SUMMARY

The present invention discloses a voltage down converter for programming a one-time-programmable (OTP) memory which comprises a bonding pad for coupling to a programming power supply, and at least one forward biased diode coupled between the bonding pad and the OTP memory, wherein a programming voltage received by the OTP memory is lowered from the programming power supply by the voltage drop across the forward biased diode, which is about 0.75V. According to one aspect of the present invention, the diode is formed by a lateral P-N junction. According to another aspect of the present invention, the diode is formed by a gate-and-drain shorted NMOS or PMOS transistor.

The construction and method of operation of the invention, however, together with additional objectives and advantages thereof will be best understood from the following description of specific embodiments when read in connection with the accompanying drawings.

### BRIEF DESCRIPTION OF THE DRAWINGS

The drawings accompanying and forming part of this specification are included to depict certain aspects of the invention. A clearer conception of the invention, and of the components and operation of systems provided with the invention, will become more readily apparent by referring to the exemplary, and therefore non-limiting, embodiments illustrated in the drawings.

FIG. 1 is a schematic diagram illustrating a voltage down converter for OTP memory programming according to an embodiment of the present invention.

FIG. 2 is schematic diagram illustrating a NMOS transistor formed diode.

FIG. 3 is schematic diagram illustrating a PMOS transistor formed diode.

### DESCRIPTION

The present invention discloses a voltage down converter that employs forward biased diodes to provide a certain amount of voltage drop. This voltage down converter is particularly fit for programming one-time-programmable (OTP) memories, as in that application accuracy is less of a concern but small layout area is much more desirable for low cost, and simplicity shortens design cycle.

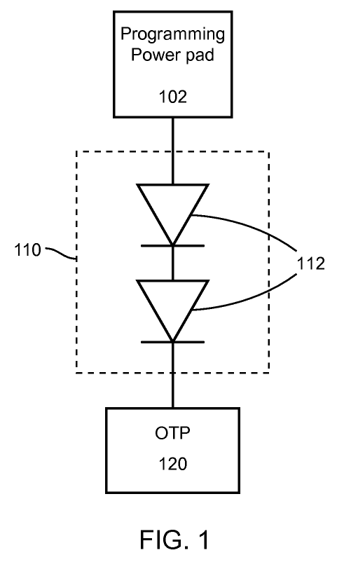

FIG. 1 is a schematic diagram illustrating a voltage down converter 110 for OTP memory programming according to an embodiment of the present invention. The voltage down converter 110 is coupled between a programming power supply bonding pad 102 and the OTP memory 120. Herein the term “coupled” means directly connected or connected through another component, but where that added another component supports the circuit function.

During a programming of the OTP memory 120, an external high voltage power source is applied at the programming power supply bonding pad 102. The voltage down converter 110 converts the high voltage to a desired low voltage that is then supplied to the OTP memory 120.

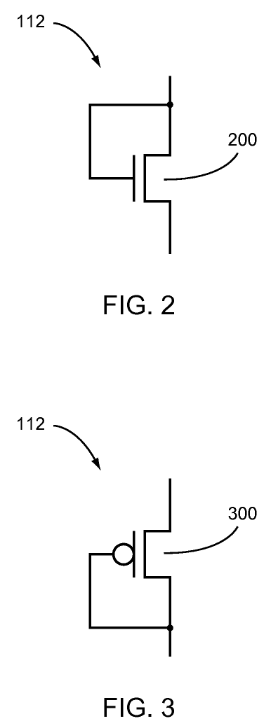

Referring again to FIG. 1, the voltage down converter 110 is comprised of two serially connected, forward-biased diodes 112. It is well-known that a forward biased diode has a nearly fixed voltage drop, such as 0.75V, across its anode and cathode. The voltage drop is determined by the diode's P-N junction characteristics and may vary in different temperatures, but such variations have no impact to OTP programming. When two diodes are serially connected, a total voltage drop across the two diodes will be a sum of the voltage drop of each individual diode. If one diode drops 0.75V, two diodes will drop 1.5V. Apparently, if more voltage drop is required, more diodes can be serially connected. In general, the total voltage drop equals 0.75*N, where N is the number of serially connected diodes. The diode 112 can be formed by a P+-N-well, or an N+-P-sub junction. An advantage of using diodes to form voltage down converter is that the diodes take much less layout area than a conventional voltage down converter employing a reference voltage generator, and the diode is much simpler to design. Often time the diode formed voltage down converter is more stable than the conventional voltage down converter. FIGS. 2 and 3 illustrate both NMOS and PMOS transistors can be used to form such diodes.

FIG. 2 is a schematic diagram illustrating a NMOS transistor 200 formed diode 112. A drain of the NMOS transistor 200 is connected to a gate thereof. When a high voltage is applied at the drain, the NMOS transistor 200 will be always on, and the voltage at the source is one P-N junction voltage drop from the drain voltage. Using the NMOS transistor 200 to form the diode 112 is because in a CMOS process, the NMOS transistor is more readily available.

FIG. 3 is a schematic diagram illustrating a PMOS transistor formed diode 112. A drain of the PMOS transistor 300 is connected to a gate thereof. When a high voltage is applied at a source, the PMOS transistor 300 will be always on, and the voltage at the drain is one P-N junction voltage drop from the source voltage. Like the NMOS transistor 200 of FIG. 2, the PMOS transistor 300 is also readily available in a CMOS process.

The above illustration provides many different embodiments or embodiments for implementing different features of the invention. Specific embodiments of components and processes are described to help clarify the invention. These are, of course, merely embodiments and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

What is claimed is:

1. A voltage down converter for programming a one-time-programmable (OTP) memory comprising:
a bonding pad for coupling to a programming power supply; and
at least one forward biased diode coupled between the bonding pad and the OTP memory,
wherein a programming voltage received by the OTP memory is lowered from the programming power supply by the voltage drop across the forward biased diode.

2. The voltage down converter of claim 1, wherein the diode is formed by a P-N junction.

3. The voltage down converter of claim 2, wherein the P-N junction has a lateral junction structure.

4. The voltage down converter of claim 1, wherein the diode is formed by a NMOS transistor, a gate of the NMOS transistor being coupled to a drain of the NMOS transistor.

5. The voltage down converter of claim 1, wherein the diode is formed by a PMOS transistor, a gate of the PMOS transistor being coupled to a drain of the PMOS transistor.

6. The voltage down converter of claim 1, wherein when there are two or more diodes coupled between the bonding pad and the OTP memory, the diodes are serially coupled with each other and all the diodes are forward biased.

7. The voltage down converter of claim 6, wherein at least one of the two or more diodes is formed by a P-N junction.

8. The voltage down converter of claim 1, wherein the OTP memory comprises a memory core and a peripheral circuit.

9. The voltage down converter of claim 8, wherein the at least one forward biased diode is coupled between the bonding pad and the memory core.

10. A voltage down converter for programming a one-time-programmable (OTP) memory comprising:
a bonding pad for coupling to a programming power supply; and
at least one forward biased P-N junction diode coupled between the bonding pad and the OTP memory,
wherein a programming voltage received by the OTP memory is lowered from the programming power supply by the voltage drop across the forward biased P-N junction diode.

11. The voltage down converter of claim 10, wherein the P-N junction diode has a lateral junction structure.

12. The voltage down converter of claim 10, wherein the P-N junction diode has a vertical junction structure.

13. The voltage down converter of claim 10, wherein when there are two or more P-N junction diodes coupled between the bonding pad and the OTP memory, the diodes are serially coupled with each other and all the P-N junction diodes are forward biased.

14. The voltage down converter of claim 13, wherein at least one of the two or more P-N junction diodes has a lateral junction structure.

15. The voltage down converter of claim 10, wherein the OTP memory comprises a memory core and a peripheral circuit.

16. The voltage down converter of claim 15, wherein the at least one forward biased P-N junction diode is coupled between the bonding pad and the memory core.

17. A voltage down converter for programming a one-time-programmable (OTP) memory comprising:
a bonding pad for coupling to a programming power supply; and
at least one NMOS transistor with a drain and a gate coupled to the bonding pad and the source coupled to the OTP memory,
wherein a programming voltage received by the OTP memory is lowered from the programming power supply by the voltage drop across the NMOS transistor.

18. The voltage down converter of claim 17, wherein when there are two or more NMOS transistor coupled between the bonding pad and the OTP memory, the NMOS transistors are serially coupled with each other and a gate of each NMOS transistor is coupled to a drain of the same.

19. The voltage down converter of claim 17, wherein the OTP memory comprises a memory core and a peripheral circuit.

20. The voltage down converter of claim 19, wherein the at least one forward biased diode is coupled between the bonding pad and the memory core.
